(19) United States
(12) Patent Application Publication
(10) Pub. No.: US 2018/0287101 A1
(43) Pub. Date: Oct. 4, 2018

(54) DISPLAY DEVICE AND METHOD OF MANUFACTURING A DISPLAY DEVICE

(71) Applicant: Japan Display Inc., Minato-ku (JP)

(72) Inventor: Takayasu Suzuki, Minato-ku (JP)

(73) Assignee: Japan Display Inc., Minato-ku (JP)

(21) Appl. No.: 15/935,333

(22) Filed: Mar. 26, 2018

(30) Foreign Application Priority Data
Mar. 29, 2017 (JP) 2017-065631

(51) Int. Cl. H01L 51/56; H01L 27/32

(52) U.S. Cl. CPC H01L 51/56; H01L 27/322; H01L 2251/568; H01L 27/3272; H01L 27/3246

(57) ABSTRACT

A display device according to an embodiment of the present invention includes: a plurality of organic light emitting diodes, each including a lower electrode, an upper electrode, and an organic material layer between the lower electrode and the upper electrode, and fluorescent material disposed on the upper electrode of at least one of the organic light emitting diodes.

### CROSS-REFERENCE TO RELATED APPLICATION

The present application claims priority from Japanese Application JP2017-65631 filed on Mar. 29, 2017, the content of which is hereby incorporated by reference into this application.

### BACKGROUND OF THE INVENTION

### 1. Field of the Invention

The present invention relates to display devices and a method of manufacturing the display devices.

### 2. Description of the Related Art

Flat panel displays, such as organic electro-luminescent (EL) display devices, have a display panel where a thin film transistor (TFT), an organic light emitting diode (OLED) and the like are formed on a substrate.

If foreign matter should enter between the cathode and the anode of such an organic light emitting diode, the foreign matter can cause short-circuit between the cathode and the anode of the OLED, resulting in a short-circuited defect. The short-circuited defect becomes a bright spot with application of a predetermined signal voltage.

Japanese Patent Laid-open Publication No. 2013-251224 discloses a technique for irradiating such a short-circuited defect with a laser beam to increase the resistance of the short-circuited defect to thereby make the defect a dark spot that does not emit light upon application of a signal voltage.

### SUMMARY OF THE INVENTION

The above conventional configuration can make a bright spot a less outstanding dark spot through laser irradiation. However, the dark spot remains.

One or more embodiments of the present invention have been conceived in view of the above, and an object thereof is to make dark spots further less outstanding in display devices.

1. A display device according to an embodiment of the present invention includes: a plurality of organic light emitting diodes, each including a lower electrode, an upper electrode, and an organic material layer between the lower electrode and the upper electrode, and fluorescent material disposed on the upper electrode of at least one of the organic light emitting diodes.

2. In the display device according to the above-mentioned item 1, the plurality of organic light emitting diodes may include first organic light emitting diodes for emission of light in a first color, the first organic light emitting diodes being arranged in a column direction, and second organic light emitting diodes for emission of light in a second color, the second organic light emitting diodes being arranged in the column direction in parallel with the first organic light emitting diodes, and the display device may further include a permeable bank disposed between some of the first organic light emitting diodes.

3. The display device according to the above-mentioned item 2 may further include a plurality of light shielding banks disposed between the first organic light emitting diodes and the second organic light emitting diodes.

4. In the display device according to any one of the above-mentioned items 1 to 3, the plurality of organic light emitting diodes may include a red organic light emitting diode for emission of red light, and the fluorescent material disposed on the upper electrode of the red organic light emitting diode may include rubrene-based material.

5. In the display device according to any one of the above-mentioned items 1 to 3, the plurality of organic light emitting diodes may include a green organic light emitting diode for emission of green light, and the fluorescent material disposed on the upper electrode of the green organic light emitting diode may include coumarin-based material.

6. In the display device according to any one of the above-mentioned items 1 to 3, the plurality of organic light emitting diodes may include a blue organic light emitting diode for emission of blue light, and the fluorescent material disposed on the upper electrode of the blue organic light emitting diode may include tris(8-quinolinorato)aluminium.

7. In the display device according to the above-mentioned item 2, the fluorescent material may be disposed on an organic light emitting diode included in the first organic light emitting diodes, and the organic light emitting diode having the fluorescent material may have a color filter disposed on the organic light emitting diode having the fluorescent material, the color filter for a color same as the first color for light emission.

8. In the display device according to any one of the above-mentioned items 1 to 7, the lower electrode included in the organic light emitting diode having the fluorescent material may have a hole formed at least in a part of the lower electrode.

9. A method of manufacturing a display device according to an embodiment of the present invention, includes: a laser irradiation step of irradiating a defective part of a plurality of organic light emitting diodes with a laser beam; and a fluorescent material application step of applying fluorescent material onto an upper electrode included in the organic light emitting diode having the defective part irradiated with the laser beam.

10. In the method of manufacturing a display device according to the above-mentioned item 9, at the laser irradiation step, electrical connection between a lower electrode included in the organic light emitting diode and a wire may be disconnected.

11. In the method of manufacturing a display device according to the above-mentioned item 9, at the laser irradiation step, foreign matter between a lower electrode and the upper electrode included in the organic light emitting diode and a part of the lower electrode in contact with the foreign matter may be removed.

### BRIEF DESCRIPTION OF THE DRAWINGS

FIG. 1 illustrates a schematic structure of a display device according to this embodiment;

FIG. 2 is a schematic plan view of a display panel of a display device according to this embodiment;

FIG. 3 is a schematic vertical cross-sectional view of the display panel along the line III-III in FIG. 2;

FIG. 4 is a schematic plan view of a pixel array portion of a display device according to this embodiment;

FIG. 5 is a schematic plan view of a pixel array portion of a display device according to this embodiment;

FIG. 6 is a schematic vertical cross-sectional view of the display panel along the line VI-VI in FIG. 5;

FIG. 7 is a schematic vertical cross-sectional view of the display panel along the line VII-VII in FIG. 5;

FIG. 8 is a flowchart of a method of repairing a bright spot in a display device according to this embodiment;

FIG. 9 is a flowchart of a method of repairing a dark spot in a display device according to this embodiment;

FIG. 10 is a schematic vertical cross-sectional view of the display panel along the line VI-VI in FIG. 5;

FIG. 11 is a schematic plan view of a display array portion of a display device according to this embodiment;

FIG. 12 is a schematic vertical cross-sectional view of the display panel along the line VI-VI in FIG. 5; and

FIG. 13 is a schematic vertical cross-sectional view of the display panel along the Line VI-VI in FIG. 5.

### DETAILED DESCRIPTION OF THE INVENTION

### First Embodiment

The following describes embodiments of the present invention, based on the drawings.

The disclosure is a mere example, and any modifications readily conceived by a person skilled in the art without departing from the gist of the present invention are included in the scope of the present invention. The respective widths, thicknesses, shapes, and so forth of respective components may be illustrated more schematically in the drawings compared with actual widths, thicknesses, shapes, and so forth in order to make clearer the description of the present invention. These, however, are mere examples, and should not limit interpretation of the present invention in any way. Any elements similar to those having been described referring to drawings referred to earlier are given the same reference numerals in the specification and drawings, and may not be described in detail again.

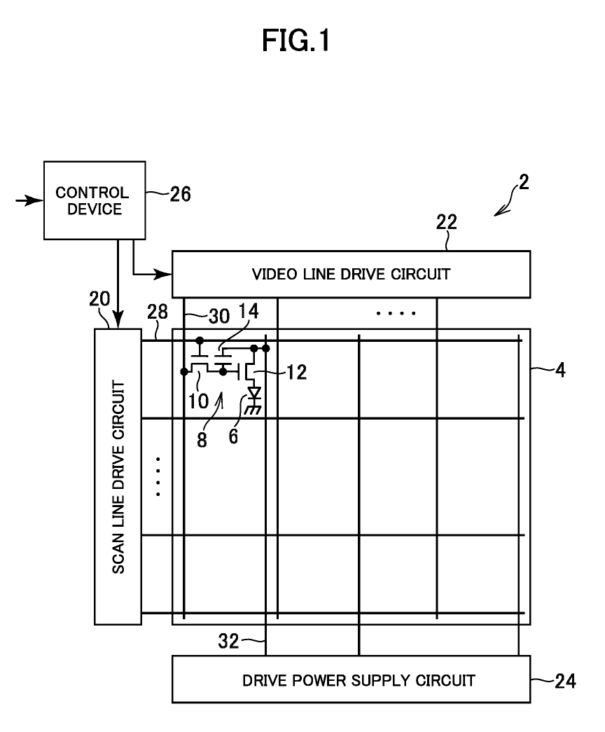

A display device 2 according to this embodiment is, for example, an organic electro-luminescent display device, which is to be mounted, for example, in television sets, personal computers, portable terminals, or portable phones. FIG. 1 schematically illustrates the structure of the display device 2 according to this embodiment. The display device 2 includes a pixel array portion 4 that displays an image and a drive unit that drives the pixel array portion 4. The display device 2 is a flexible display device and includes a base member and a wire layer including a wire disposed inside or above the base member, the base member being made using a flexible resin film, for example.

The pixel array portion 4 has organic light emitting diodes 6 and pixel circuits 8 arranged in a matrix, each corresponding to each pixel. The pixel circuit 8 includes, for example, a lighting thin film transistor (TFT) 10, a drive TFT 12, and a capacitor 14.

The drive unit includes a scan line drive circuit 20, a video line drive circuit 22, a drive power supply circuit 24, and a control device 26, and drives the pixel circuit 8 to control light emission from the organic light emitting diode 6.

The scan line drive circuit 20 is connected to scan signal lines disposed each for every row of the pixels in the horizontal direction (a pixel row). The scan line drive circuit 20 sequentially selects a scan signal line 28 in response to a timing signal received from the control device 26, and applies a voltage for turning on the lighting TFT 10 to the selected scan signal line 28.

The video line drive circuit 22 is connected to video signal lines 30 disposed each for every column of the pixels in the vertical direction (a pixel column). The video line driving circuit 22 receives video signals from the control device 26, and, in accordance with the scan signal line 28 selected by the scan line drive circuit 20, outputs voltage corresponding to a video signal of the selected pixel row to each of video signal lines 30. The voltage is written into the capacitor 14 via the lighting TFT 10 in the selected pixel row. The drive TFT 12 supplies a current in accordance with the voltage written to the organic light emitting diode 6. With the above, the organic light emitting diode 6 corresponding to the selected scan signal line 28 emits light.

The drive power supply circuit 24 is connected to a drive power supply line 32 provided for every pixel column and supplies a current to the organic light emitting diode 6 via the drive power supply line 32 and the drive TFT 12 of the pixel row selected.

The lower electrode of the organic light emitting diode 6 is connected to the drive TFT 12. The upper electrode of each organic light emitting diode 6 is made using an electrode that is common to the organic light emitting diodes 6 of all pixels. In the case of a lower electrode functioning as a positive electrode (an anode), the lower electrode receives a high potential, and the upper electrode, functioning as a negative electrode (a cathode), receives a lower potential. Meanwhile, in the case of a lower electrode functioning as a negative electrode (a cathode), the lower electrode receives a lower potential, and the upper electrode, functioning as a positive electrode (an anode), receives a higher potential.

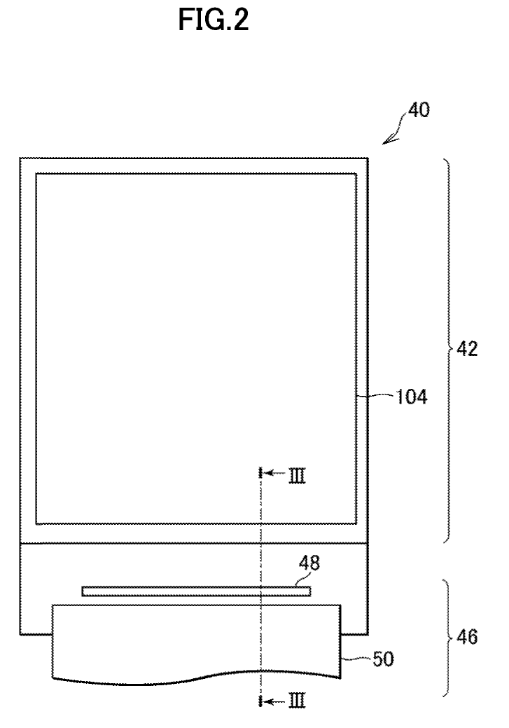

FIG. 2 is a schematic plan view of the display panel 40 of the display device 2. The display panel 40 has the pixel array portion 4 illustrated in FIG. 1, formed in the display area 42 thereof. As described above, the organic light emitting diode 6 is disposed in the pixel array portion 4. As described above, an upper electrode 104 of the organic light emitting diode 6 is formed common to the respective pixels, covering substantially the entire display area 42.

The display panel 40, which is rectangular, has a drive unit formation area 46 defined along one side of the display panel 40. A wire for connection to the display area 42 is disposed in the drive unit formation area 46. The drive unit formation area 46 additionally has a drive IC 48 that constitutes a drive unit, and is connected to flexible printed circuits (FPC) 50. The FPC 50 is connected to, for example, the scan line drive circuit 20, the video line drive circuit 22, the drive power supply circuit 24, and the control device 26, and has an integrated circuit (IC) formed thereon.

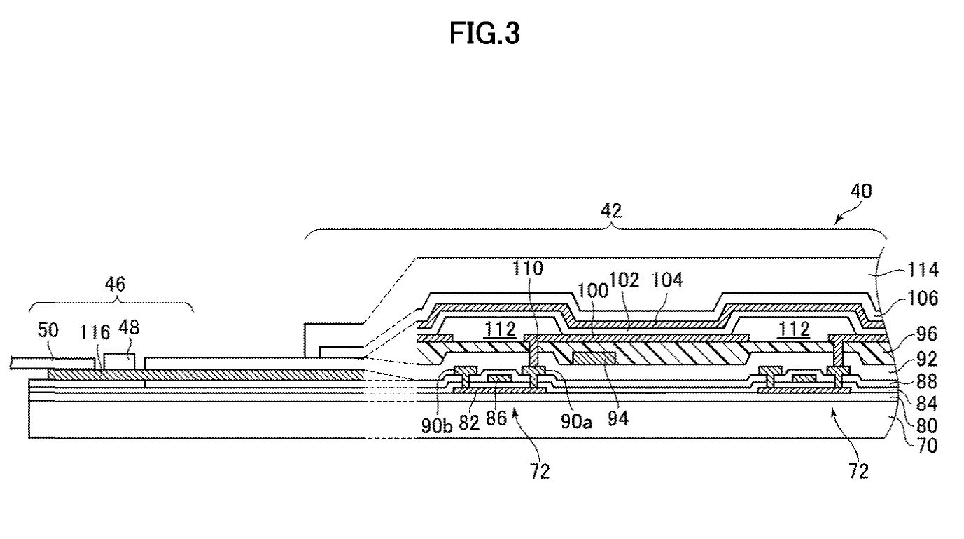

FIG. 3 is a schematic vertical cross-sectional view of the display panel 40 along the line III-III in FIG. 2. The display panel 40 has a laminated structure including a circuit layer, the organic light emitting diode 6, and a sealing layer 106 stacked in this order on an insulating base member 70 made using a resin film, the circuit layer including a TFT 72, the sealing layer 106 sealing the organic light emitting diode 6. The insulating base member 70 may be made, for example, using a polyimide film. A protective film 114 can be formed on the sealing layer 106. The pixel array portion 4 in this embodiment is of a top-emission type. The light generated by the organic light emitting diode 6 ejects toward the side opposite from the insulating base member 70, that is, upward in FIG. 3. In the case where the display device 2 employs color filters for coloring, a color filter is disposed between the sealing layer 106 and the protective film 114 or on the side closer to the counter substrate. The organic light emitting diode 6 generates a white light, which passes through the color filters to thereby constituting red (R), green (G), and blue (B) respective light beams.

The circuit layer in the display area 42 has the above-mentioned pixel circuit 8, scan signal line 28, video signal line 30, drive power supply line 32, or the like. At least a part of the drive unit can be formed as a circuit layer on the insulating base member 70 in an area adjacent to the display area 42. As described above, the FPC 50 and the drive IC 48 constituting the drive unit can be connected to a wire 116 in the circuit layer in the drive unit formation area 46.

Specifically, a polysilicon (p-Si) film is formed on the insulating base member 70 via a first insulating film 80, or a base layer made of inorganic insulating material, such as silicon nitride (SiN_{y}) or silicon oxide (SiOₓ). The p-Si film is patterned such that a part thereof to be used in the circuit layer is selectively left. For example, using the p-Si film, a semiconductor area 82 that makes a channel portion and the source and drain portions of a top-gate TFT 72 is formed. On the channel portion of the TFT 72, a gate electrode 86 is disposed via a gate insulating film 84. The gate electrode 86 is formed by patterning a metal film formed through sputtering or the like. Thereafter, an interlayer insulating film 88 is formed covering the gate electrode 86. The p-Si that makes the source portion and drain portion of the TFT 72 is doped with impurities through ion injection, and a source electrode 90a and a drain electrode 90b for electrical connection thereto are formed. After formation of the TFT 72 as described above, an interlayer insulating film 92 is formed. On the surface of the interlayer insulating film 92, a wire 94 or the like can be formed through patterning with a metal film formed through sputtering or the like. This metal film and a metal film used to form the gate electrode 86, the source electrode 90a, and the drain electrode 90b together constitute a multi-layered wire structure including, for example, the wire 116 and the scan signal line 28, the video signal line 30, and the drive power supply line 32 illustrated in FIG. 1. On the structure, for example, a planarization film 96 made of organic material such as acrylic resin or the like is formed, and the organic light emitting diode 6 is formed on the thus flattened surface of the display area 42.

The organic light emitting diode 6 includes a lower electrode 100, an organic material layer 102, and the upper electrode 104, laminated in this order from the insulating base member 70 side. In this embodiment, the lower electrode 100 is a positive electrode (an anode) of the organic light emitting diode 6, and the upper electrode 104 is a negative electrode (a cathode). The organic material layer 102 includes a hole transport layer, a light emissive layer, an electron transport layer, or the like.

In the case where the TFT 72 illustrated in FIG. 3 is a drive TFT 12 including an n-channel, the lower electrode 100 is connected to the source electrode 90a of the TFT 72. Specifically, after formation of the above mentioned planarization film 96, a contact hole 110, through which the lower electrode 100 is to be connected to the TFT 72, is formed, and a conductive film is formed on the surface of the planarization film 96 and inside the contact hole 110 and then patterned, whereby the lower electrode 100 connected to the TFT 72 is formed for every pixel.

After formation of the lower electrode 100, a bank 112 is formed on the boundary between pixels. In the effective area of the pixel, defined by the surrounding bank 112, the lower electrode 100 remains exposed. After formation of the bank 112, the respective layers constituting the organic material layer 102 are laminated in order on the lower electrode 100. The upper electrode 104 is formed on the organic material layer 102, using transparent electrode material.

On the surface of the upper electrode 104, for example, an SiN_{y} film is formed as the sealing layer 106 by chemical vapor deposition (CVD). In order to secure mechanical endurance of the surface of the display panel 40, the protective film 114 is formed on the surface of the display area 42. Meanwhile, to facilitate connection of an IC or an FPC, the protective film 114 is not formed on the drive unit formation area 46. The wires of the FPC 50 or terminals of the driver IC 48 are electrically connected to, for example, the wire 116.

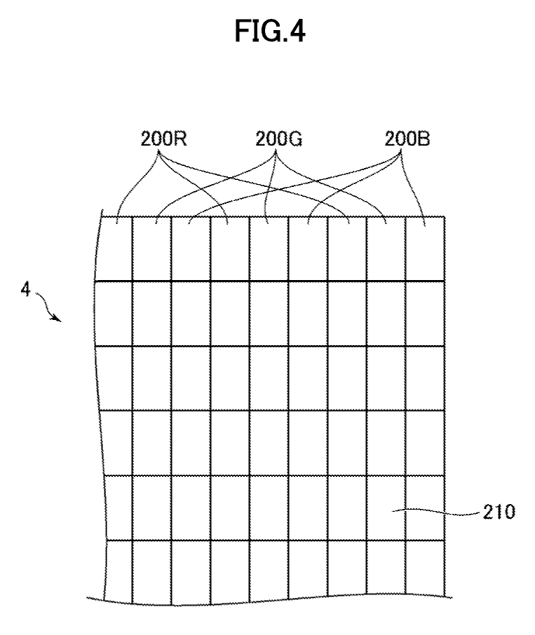

FIG. 4 is a schematic plan view of the pixel array portion 4 of the display device 2. As illustrated in FIG. 4, the pixel array portion 4 has a plurality of pixels, each pixel having an organic light emitting diode 6 for light emission in any of the colors including red, green, and blue. In this embodiment, the organic light emitting diodes for the same color are disposed in each column. That is, a pixel column 200R for red light emission, a pixel column 200G for green light emission, and a pixel column 200B for blue light emission are sequentially disposed.

In this embodiment, an example will be described in which the pixel column 200G for green light emission includes a bright spot 210, or a spot that lights constantly. The bright spot 210 is caused, for example, as the lower electrode 100, or an anode, of the organic light emitting diode 6 of this pixel is connected to a wire or the like having an irregular shape due to abnormality in process.

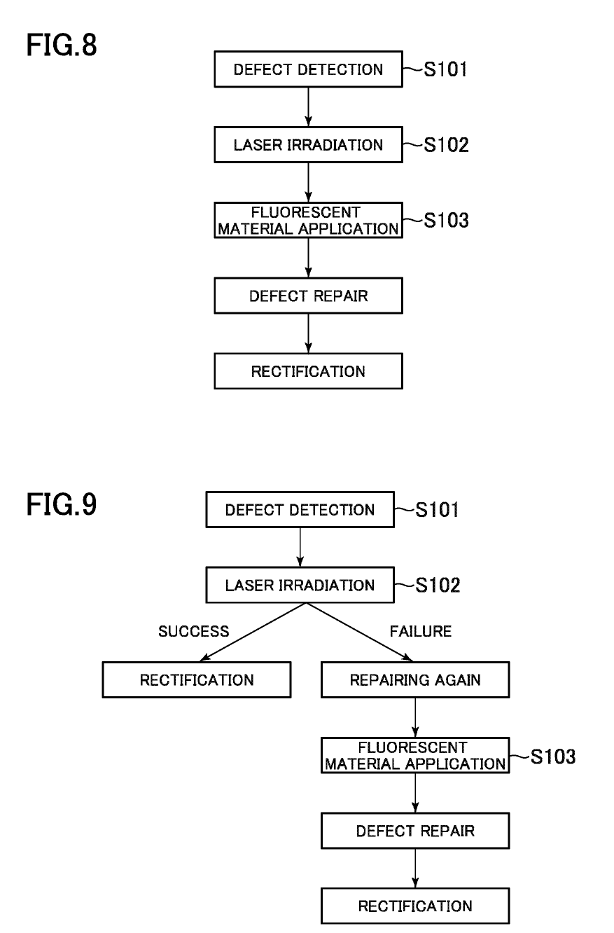

The following describes a method of repairing a bright spot in this embodiment, referring to the flowchart in FIG. 8.

Initially, at a defect detection step S101, a bright spot is detected. In this embodiment, as illustrated in FIG. 4, the position of a bright spot 210 in the pixel column 200G for green light emission is detected. The detection may be made by any method without limitation. For example, scattered light or reflection light attributed to the light emitted from the display surface side of the display panel 40 may be imaged by a detector to thereby obtain an optical image of the display panel 40, and whether there is a defect in the optical EL device is determined based on the optical image.

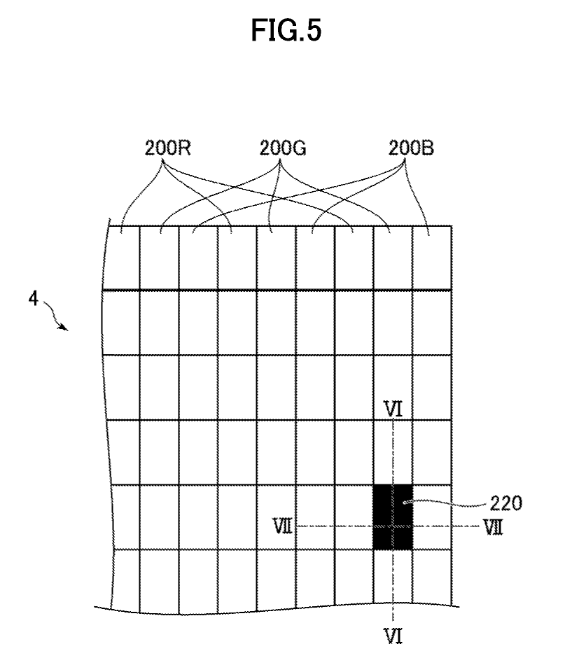

Thereafter, a laser irradiation step S102 of irradiating an object pixel with a laser beam is performed. Specifically, the bright spot 210 is irradiated with a laser beam emitted from the display surface side of the display panel 40, that is, the upper electrode 104 side, to thereby disconnect the connection between the lower electrode 100 and a wire having an irregular shape. That is, the organic light emitting diode 6 and the pixel circuit 8 in the relevant pixel are disconnected from each other. This can make the bright spot 210 a dark spot 220, or a spot that does not light at all, as illustrated in FIG. 5. The laser irradiation step S102 resultantly causes a hole in a part of the lower electrode 100 due to laser irradiation. Laser beams can be emitted from the insulating base member 70 side, though laser beam irradiation from the upper electrode 104 side is preferred. Laser beam irradiation from the upper electrode 104 side enables efficient execution of the laser irradiation step S102 as no TFT layer 72, or the like, containing a TFT 72 forming a part of the pixel circuit 8 is present in the laser beam path.

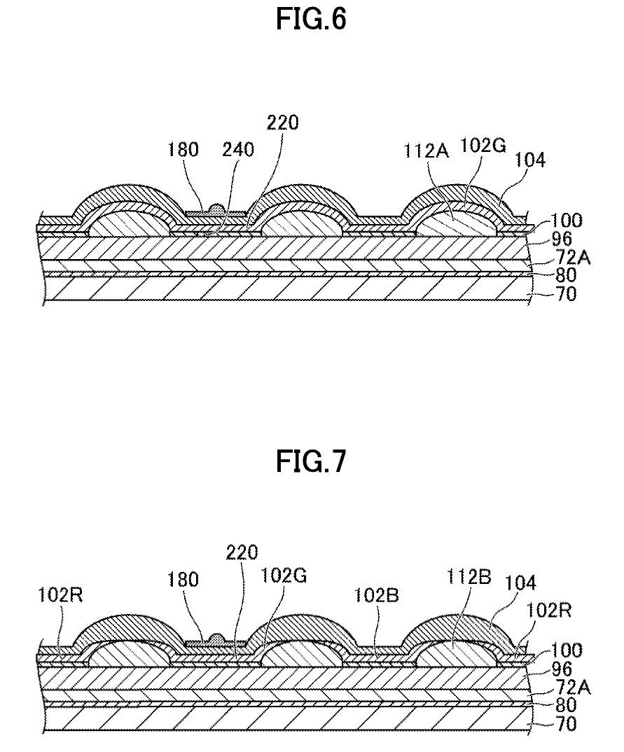

Thereafter, a fluorescent material application step S103 is performed. FIG. 6 is a schematic vertical cross-sectional view of the display panel 40 along the line VI-VI in FIG. 5. FIG. 6 is a simplified version of the cross-sectional view in FIG. 3. In FIG. 6, the first insulating film 80 is formed on the insulating base member 70, and the TFT layer 72A containing the TFT 72 is formed on the insulating film 80. The planarization film 96 is formed on the TFT layer 72A, and the lower electrode 100 is formed on the planarization film 96. In this embodiment, the lower electrode 100 is an anode, and has a hole 240 resulted at the laser irradiation step S102. The organic material layer 102 and the bank 112 are formed on the lower electrode 100, the bank 112 being formed between pixels. As FIG. 6 illustrates a vertical cross section of the pixel column 200G for green light emission illustrated in FIG. 5, the organic material layer 102 here is an organic material layer 102G that emits green light upon application of a voltage. The bank 112 formed between the organic material layers 102G that emit light in the same color, or green here, is a permeable bank 112A. A cathode, or the upper electrode 104, is formed on the upper surface of the organic material layer 102.

The pixel column 200G for green light emission contains a dark spot 220, which used to be a bright spot 210 and is darkened by laser irradiation. The dark spot 220 does not emit green light despite application of a voltage to the relevant anode and cathode. Regarding this point, in this embodiment, at the fluorescent material application step S103, fluorescent material 180 is applied onto the cathode, that is, the upper electrode 104 of the pixel that makes the dark spot 220. The fluorescent material 180 is material that absorbs green light and emits green fluorescent light and is, for example, coumarin-based material. With this structure, green light emitted from an adjacent pixel passes through the permeable bank 112A made of permeable material and enters the fluorescent material 180. The fluorescent material 180 absorbs the green light and emits green fluorescent light. As a result, as illustrated in the plan view in FIG. 11, the dark spot 220 is compensated for color, and becomes less outstanding. That is, the defect is repaired and then rectified.

The permeable bank 112A may be made of material having permeability at least in the wavelength range for green light. Although coumarin-based material that absorbs green light and emits green fluorescent light is mentioned as the fluorescent material 180 in this embodiment, any material that emits at least green fluorescent light is applicable. Material that additionally emits light in a wavelength range other than that for green is applicable. In the case where the fluorescent material 180 additionally emits light in a wavelength range other than that for green light, a green color filter may be disposed on the upper surface side of the material so that only green light can be extracted.

FIG. 7 is a schematic vertical cross-sectional view of the display panel 40 along the line VII-VII in FIG. 5. FIG. 7 illustrates a simplified version of the cross-sectional view illustrated in FIG. 3, similar to FIG. 6. An organic material layer 102 is formed on the upper surface of the lower electrode 100. As FIG. 7 illustrates a vertical cross section along a line traversing the pixel column 200R for red light emission, the pixel column 200G for green light emission, and the pixel column 200B for blue light emission illustrated in FIG. 5, the organic material layer 102 includes an organic material layer 102R, an organic material layer 102G, and an organic material layer 102B that emit red, green, and blue respective light beams upon application of a voltage thereto. A cathode, or the upper electrode 104, is formed on the upper surface of the organic material layer 102.

A light shielding bank 112B is formed between a pixel including the organic material layer 102G for green light emission and another pixel for emission of light in another color. This structure can prevent mixture of green light emitted from the fluorescent material 180 on the organic light emitting diode for green light emission and light in other colors emitted from other pixels.

Although an example is described in this embodiment in which a green organic light emitting diode including the organic material layer 102G for green light emission becomes a bright spot 210 and the bright spot 210 is darkened to be rectified later, the above description is applicable to a case in which an optical light emitting diode including the organic material layer 102R for red light emission or the organic material layer 102B for blue light emission becomes a bright spot 210.

In the case where a red organic light emitting diode including the organic material layer 102R for red light emission becomes a bright spot 210, material, such as rubrene-based material, that absorbs red light and emits red fluorescent light may be used as the fluorescent material 180 to be disposed on the upper electrode 104 of the red organic light emitting diode that is darkened at the laser irradiation step S102. In the case where the fluorescent material 180 additionally emits light in a wavelength range other than that for red, a red color filter may be disposed on the upper surface side of the fluorescent material 180, so that only red light can be extracted. In this case, the permeable bank 112A for use in the pixel column 200R for red light emission may be made of any permeable material having permeability at least in the wavelength range for red light.

Similarly, in the case where a blue organic light emitting diode including the organic material layer 102B for blue light emission becomes a bright spot, material, such as tris(8-quinolinorato)aluminium, that absorbs blue light and emits blue fluorescent light may be used as the fluorescent material 180 to be disposed on the upper electrode 104 of the blue organic light emitting diode that is darkened at the laser irradiation step S102. In the case where the fluorescent material 180 additionally emits light in a wavelength range other than that for blue, a blue color filter may be disposed on the upper surface side of the fluorescent material 180, so that only blue light can be extracted. In this case, the permeable bank 112A for use in the pixel column 200B for blue light emission may be made of any permeable material having permeability at least in the wavelength range for blue light.

Thereafter, the sealing layer 106 illustrated in FIG. 3 is formed over the entire upper electrode 104. As the sealing layer 106 covers the repaired part described above, invasion of moisture or oxygen through the repaired part into the display panel 40 can be prevented.

The following describes a method of repairing a defect in the case where the organic light emitting diode 6 makes a dark spot 220, referring to the flowchart in FIG. 9.

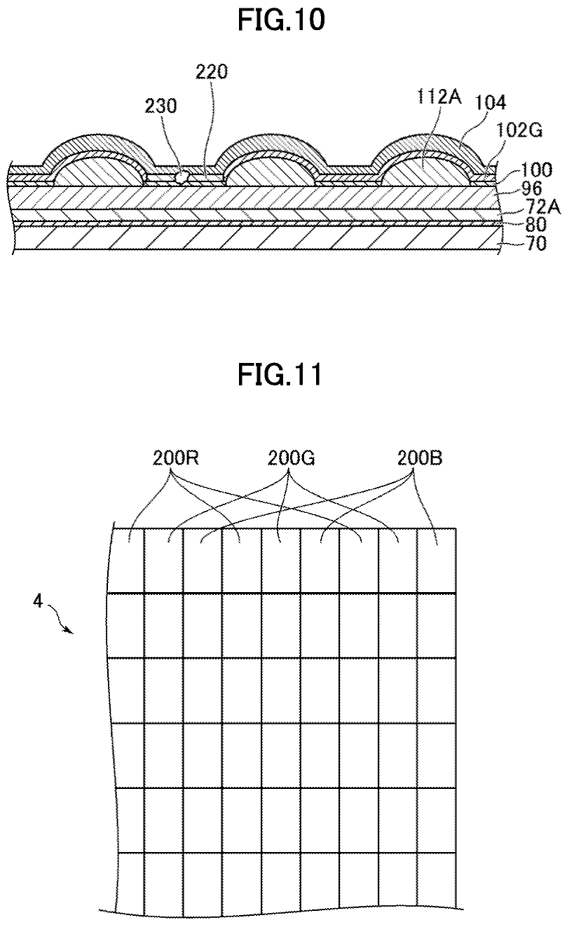

For example, as illustrated in FIG. 10, if foreign matter should enter between the upper electrode 104 and the lower electrode 100 and causes short-circuit between the cathode and the anode, the organic light emitting diode 6 makes a dark spot 220.

In this case as well, the defect detection step S101 and the laser irradiation step S102, described referring to FIG. 9, are executed. That is, a laser beam is emitted from the upper surface side of the display panel 40 to remove the foreign matter and a part of the lower electrode 100, the part being in contact with the foreign matter. At this step, although light is not emitted from where a part of the organic material layer 102 has been removed, the remaining part of the organic material layer 102 in the same pixel emits light. Using the light from the remaining part, the fluorescent material 180 disposed on the upper surface of the upper electrode 104 can emit light. That is, as the fluorescent material 180 can emit light using the light from the same pixel in this case, as described above, the permeable bank 112A is unnecessary. This allows formation of all banks 112 as the light shielding banks 11B. When the dark spot 220 is rectified by this laser irradiation, the repairing process completes.

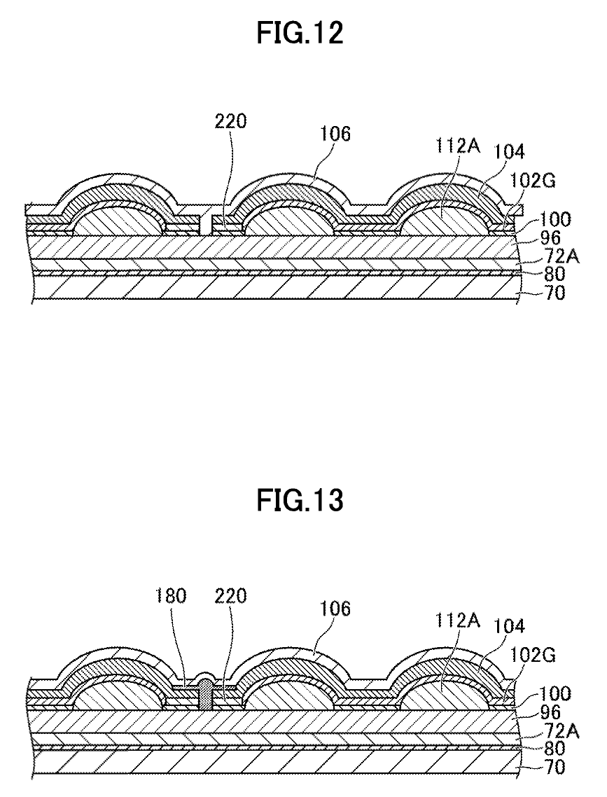

Thereafter, as illustrated in FIG. 12, the sealing layer 106 is formed on the entire upper electrode 104. As the sealing layer 106 covers the repaired part, invasion of moisture and oxygen through the repaired part into the display panel 40 can be prevented. As illustrated in FIG. 12, the sealing layer 106 may fill inside the repaired part, and the fluorescent material 180 may reach the planarization film 96.

If the foreign matter 230 cannot be fully removed by the laser irradiation at the laser irradiation step S102 or the dark spot 220 cannot be fully rectified despite removal of the foreign matter 230, the above mentioned fluorescent material application step S103 is executed as illustrated in FIG. 13 to apply the fluorescent material 180 onto the part irradiated with the laser. This can repair the defect, and the dark spot 220 can be rectified. As illustrated in FIG. 13, the fluorescent material 180 may fill inside the repaired part and reach the planarization film 96.

Note that a person skilled in the art can conceive various kinds of changes and modifications within the gist of the present invention. Such changes and modifications are included in the scope of the present invention. For example, any addition, deletion, change in design of any structural components, addition and deletion of a process, and change in a condition are included in the scope of the present invention when these retain the gist of the present invention.

What is claimed is:

1. A display device, comprising:
a plurality of organic light emitting diodes, each including
a lower electrode,
an upper electrode, and
an organic material layer between the lower electrode and the upper electrode, and
fluorescent material disposed on the upper electrode of at least one of the organic light emitting diodes.

2. The display device according to claim 1, wherein
the plurality of organic light emitting diodes include
first organic light emitting diodes for emission of light in a first color, the first organic light emitting diodes being arranged in a column direction, and
second organic light emitting diodes for emission of light in a second color, the second organic light emitting diodes being arranged in the column direction in parallel with the first organic light emitting diodes, and
the display device further comprises a permeable bank disposed between some of the first organic light emitting diodes.

3. The display device according to claim 2, further comprising a plurality of light shielding banks disposed between the first organic light emitting diodes and the second organic light emitting diodes.

4. The display device according to claim 1, wherein
the plurality of organic light emitting diodes include a red organic light emitting diode for emission of red light, and
the fluorescent material disposed on the upper electrode of the red organic light emitting diode includes rubrene-based material.

5. The display device according to claim 1, wherein
the plurality of organic light emitting diodes include a green organic light emitting diode for emission of green light, and
the fluorescent material disposed on the upper electrode of the green organic light emitting diode includes coumarin-based material.

6. The display device according to claim 1, wherein
the plurality of organic light emitting diodes include a blue organic light emitting diode for emission of blue light, and
the fluorescent material disposed on the upper electrode of the blue organic light emitting diode includes tris(8-quinolinorato)aluminium.

7. The display device according to claim 2, wherein
the fluorescent material is disposed on an organic light emitting diode included in the first organic light emitting diodes, and
the organic light emitting diode having the fluorescent material has a color filter disposed on the organic light emitting diode having the fluorescent material, the color filter for a color same as the first color for light emission.

8. The display device according to claim 1, wherein the lower electrode included in the organic light emitting diode having the fluorescent material has a hole formed at least in a part of the lower electrode.

9. A method of manufacturing a display device, comprising:
a laser irradiation step of irradiating a defective part of a plurality of organic light emitting diodes with a laser beam; and
a fluorescent material application step of applying fluorescent material onto an upper electrode included in the organic light emitting diode having the defective part irradiated with the laser beam.

10. The method of manufacturing the display device according to claim 9, wherein at the laser irradiation step, electrical connection between a lower electrode included in the organic light emitting diode and a wire is disconnected.

11. The method of manufacturing the display device according to claim 9, wherein at the laser irradiation step, foreign matter between a lower electrode and the upper electrode included in the organic light emitting diode and a part of the lower electrode in contact with the foreign matter are removed.
